(19) United States
(12) Patent Application Publication
(10) Pub. No.: US 2025/0055427 A1
(43) Pub. Date: Feb. 13, 2025

(54) RADIO FREQUENCY AMPLIFICATION CIRCUIT

(71) Applicant: Murata Manufacturing Co., Ltd., Kyoto (JP)

(72) Inventors: Takayuki TSUTSUI, Kyoto (JP); Shinnosuke TAKAHASHI, Kyoto (JP)

(21) Appl. No.: 18/932,829

(22) Filed: Oct. 31, 2024

Related U.S. Application Data
(63) Continuation of application No. PCT/JP2023/016501, filed on Apr. 26, 2023.

(30) Foreign Application Priority Data
May 17, 2022 (JP) 2022-080886

(51) Int. Cl. H03F 3/213; H03F 1/30

(52) U.S. Cl. CPC H03F 3/213; H03F 1/302; H03F 2200/451

(57) ABSTRACT

A radio frequency amplification circuit includes an amplification transistor, a first transistor, and a Schottky barrier diode. The amplification transistor has a base to which a radio frequency signal is supplied and a collector from which the radio frequency signal amplified is outputted, and is made of a compound semiconductor. The first transistor has a base to which a first bias is supplied, and an emitter electrically coupled to the base of the amplification transistor and configured to supply a second bias to the base of the amplification transistor, and is made of the compound semiconductor. The Schottky barrier diode has an anode electrically coupled to the base of the first transistor and a cathode electrically coupled to the emitter of the first transistor.

### CROSS REFERENCE TO RELATED APPLICATION

This is a continuation of International Application No. PCT/JP2023/016501 filed on Apr. 26, 2023 which claims priority from Japanese Patent Application No. 2022-080886 filed on May 17, 2022. The contents of these applications are incorporated herein by reference in their entireties.

### BACKGROUND ART

### Technical Field

The present disclosure relates to a radio frequency amplification circuit.

A radio frequency amplification circuit (RF amplification circuit) is mounted on a mobile communication device such as a portable terminal, for example. A lithium-ion battery is used in a mobile communication device in most cases, and in recent years, further lowering of a minimum power supply voltage has been required in order to extend discharge characteristics of a battery.

Further, the RF amplification circuit is required to have a higher output and to cope with a higher frequency. A transistor made of a compound semiconductor can have a higher output in a high frequency band as compared with a transistor made of an elemental semiconductor, and thus the transistor made of a compound semiconductor is often used in a mobile communication device.

There is a high output amplifier intended to suppress a drop in a base voltage of an amplification element and to prevent a decrease in output power at a time of a large signal (for example, Patent Document 1). The high output amplifier includes an amplification element to amplify an input signal and a circuit to supply a bias to the amplification element. The high output amplifier described in Patent Document 1 is provided with an emitter follower circuit and a switch circuit to apply a power supply voltage to the amplification element through a switch as a circuit to supply the bias to the amplification element. The emitter follower circuit supplies a bias voltage to the amplification element. The switch circuit is coupled to the amplification element in parallel with the emitter follower circuit. When a voltage applied across both ends of the switch exceeds a threshold value, a bias current is supplied to the amplification element not only from the emitter follower circuit but also from the switch circuit.

Patent Document 1: Japanese Unexamined Patent Application Publication No. 2016-116022

Patent Document 2: Japanese Unexamined Patent Application Publication No. 2022-36687

### BRIEF SUMMARY

A threshold voltage of a transistor made of a compound semiconductor is higher than a threshold voltage of a transistor made of an elemental semiconductor. Because of that, there is a problem that a transistor made of a compound semiconductor does not operate when a power supply voltage supplied from a battery is low (hereinafter, may be referred to as at a low voltage).

In Patent Document 1, graphs illustrating changes in a base current (Ib), a base voltage (Vb), and output power for input power are described. Considering characteristics in these graphs when the input power is small, it is conceivable that the transistor described in Patent Document 1 is made of an elemental semiconductor.

Since a threshold voltage of a transistor made of an elemental semiconductor is low, the transistor operates even at a low voltage. Further, Patent Document 1 does not refer to bias supply at a low voltage for a transistor made of a compound semiconductor.

The present disclosure provides a radio frequency amplification circuit including a transistor made of a compound semiconductor, which is, at a low voltage, capable of increasing a gain when the power of an input signal is small.

A radio frequency amplification circuit according to an aspect of the present disclosure includes an amplification transistor having a base to which a radio frequency signal is supplied and a collector from which the radio frequency signal amplified is outputted, the amplification transistor made of a compound semiconductor; a first transistor having a base to which a first bias is supplied and an emitter electrically coupled to the base of the amplification transistor and configured to supply a second bias to the base of the amplification transistor, the first transistor made of the compound semiconductor; and a Schottky barrier diode having an anode electrically coupled to the base of the first transistor and a cathode electrically coupled to the emitter of the first transistor.

A radio frequency amplification circuit according to another aspect of the present disclosure includes an amplification transistor having a base to which a radio frequency signal is supplied and a collector from which the radio frequency signal amplified is outputted; a first transistor having a base to which a first bias is supplied and an emitter electrically coupled to the base of the amplification transistor and configured to supply a second bias to the base of the amplification transistor; and a Schottky barrier diode having an anode electrically coupled to the base of the first transistor and a cathode electrically coupled to the emitter of the first transistor. A threshold voltage of the Schottky barrier diode is lower than a threshold voltage of the first transistor.

According to the present disclosure, it is possible to provide a radio frequency amplification circuit including a transistor made of a compound semiconductor, which is, at a low voltage, capable of increasing a gain when the power of an input signal is small.

### BRIEF DESCRIPTION OF THE DRAWINGS

FIG. 1 is a circuit diagram of an RF amplification circuit 1.

FIG. 2 is a graph illustrating an example of a change of V-I characteristics of a Schottky barrier diode 327 that depends on temperature.

FIG. 3 is a graph illustrating an example of a change of V-I characteristics of an EB diode between an emitter and a base in a diode-coupled transistor that depends on temperature.

FIG. 4 is a circuit diagram of an RF amplification circuit 91 that is a first reference example of the RF amplification circuit 1.

FIG. 5 is a graph illustrating an example of AM-AM characteristics.

FIG. 6 is a graph illustrating an example of AM-PM characteristics.

FIG. 7 is a circuit diagram of an RF amplification circuit 11 described in Patent Document 2, which is a second reference example of the RF amplification circuit 1.

FIG. 8 is a circuit diagram of an RF amplification circuit 2.

### DETAILED DESCRIPTION

Hereinafter, embodiments of the present disclosure will be described in detail with reference to the drawings. The same elements are denoted by the same reference signs, and duplicated description will be omitted as much as possible.

### First Embodiment

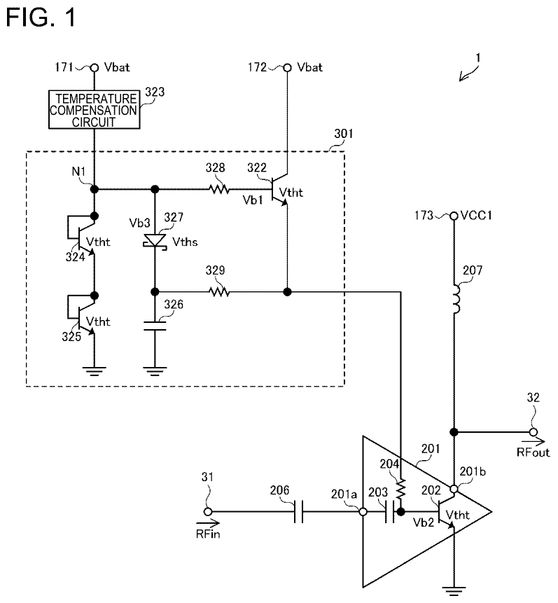

A radio frequency (hereinafter, may be referred to as RF) amplification circuit according to a first embodiment will be described. FIG. 1 is a circuit diagram of an RF amplification circuit 1. As illustrated in FIG. 1, the RF amplification circuit 1 (power amplification circuit) includes an amplifier 201, a capacitor 206, an inductor 207, a bias supply circuit 301, and a temperature compensation circuit 323.

The amplifier 201 includes an input terminal 201a, an output terminal 201b, an amplification transistor 202, a capacitor 203, and a resistor 204. The bias supply circuit 301 includes a biasing transistor 322 (first transistor), transistors 324 and 325, a capacitor 326, a Schottky barrier diode 327, and resistors 328 and 329.

In the embodiment, the amplification transistor 202, the biasing transistor 322, and the transistors 324 and 325 are each described as being a bipolar transistor such as a heterojunction bipolar transistor (HBT). The transistor is made of a compound semiconductor. The compound semiconductor is a semiconductor containing gallium arsenide (GaAs) as a main component, for example. The transistor may be made of another semiconductor material.

The transistor may be another transistor such as a metal-oxide-semiconductor field-effect transistor (MOSFET). In the case above, a base, a collector, and an emitter may be replaced with a gate, a drain, and a source, respectively.

An input signal RFin, which is an RF signal, is inputted to an input terminal 31. Battery voltage supply terminals 171 and 172 supply a battery voltage Vbat. A power voltage supply terminal 173 supplies a power supply voltage VCC1 for the amplification transistor 202 in the amplifier 201 to operate.

The input terminal 201a of the amplifier 201 is coupled to the input terminal 31 through the capacitor 206. The output terminal 201b of the amplifier 201 is coupled to the power voltage supply terminal 173 through the inductor 207 and to an output terminal 32.

The amplifier 201 amplifies the input signal RFin inputted from the input terminal 201a and outputs an amplified output signal RFout to the output terminal 32.

In detail, the capacitor 203 in the amplifier 201 has a first end coupled to the input terminal 201a and a second end. The resistor 204 has a first end coupled to the bias supply circuit 301 and a second end coupled to the second end of the capacitor 203.

The amplification transistor 202 includes a base coupled to the second end of the capacitor 203 and to be supplied with the input signal RFin, a collector coupled to the output terminal 201b and to output the output signal RFout, and an emitter coupled to the ground.

The bias supply circuit 301 supplies a bias voltage Vb2 to the base of the amplification transistor 202. The bias voltage Vb2 is a concrete example of a “second bias” in the present disclosure. The second bias may be a bias current.

In detail, the biasing transistor 322 in the bias supply circuit 301 has a base coupled to a node N1 through the resistor 328, a collector coupled to the battery voltage supply terminal 172, and an emitter electrically coupled to the base of the amplification transistor 202 through the resistor 204. The resistor 328 is provided for current adjustment, for example.

The collector and the base of the biasing transistor 322 are supplied with the battery voltage Vbat and a bias voltage Vb1, respectively. The emitter of the biasing transistor 322 supplies the bias voltage Vb2 to the base of the amplification transistor 202. The bias voltage Vb1 is a concrete example of a “first bias” in the present disclosure. The first bias may be a bias current.

The Schottky barrier diode 327 has an anode coupled to the node N1 and a cathode coupled to the emitter of the biasing transistor 322 through the resistor 329. The resistor 329 is provided for current adjustment, for example.

A threshold voltage Vths of the Schottky barrier diode 327 is lower than a threshold voltage Vtht between the base and the emitter of the biasing transistor 322. Specifically, the threshold voltage Vths of the Schottky barrier diode 327 is 0.6 V to 0.7 V. The biasing transistor 322 has the threshold voltage Vtht of approximately 1.35 V. The threshold voltage Vtht between the base and the emitter of each of the amplification transistor 202 and the transistors 324 and 325 is also approximately 1.35 V.

The temperature compensation circuit 323 and the transistors 324 and 325 supply the bias voltage Vb1 and a bias voltage Vb3 to the base of the biasing transistor 322 and the anode of the Schottky barrier diode 327, respectively, on the basis of the battery voltage Vbat supplied from the battery voltage supply terminal 171.

In detail, the transistor 324 has a collector coupled to the node N1, a base coupled to the collector, and an emitter. Hereinafter, a coupling between a collector of a transistor and a base of the transistor may be referred to as a diode coupling.

The transistor 325 is diode-coupled and has a collector coupled to the emitter of the transistor 324 and an emitter coupled to the ground. Since each of the transistors 324 and 325 functions as a diode, a voltage drop corresponding to two diodes occurs in a path between the collector and the emitter of the transistor 324 and a path between the collector and the emitter of the transistor 325.

That is, a voltage of the collector and the base of the transistor 324 when the ground is used as a reference, which is the bias voltage Vb3, is a voltage of a level corresponding to a voltage drop corresponding to two diodes.

Note that, although the bias voltage Vb3 is higher than the bias voltage Vb1 by a voltage drop in the resistor 328 caused by a base current of the biasing transistor 322, the bias voltage Vb3 is not greatly different from the bias voltage Vb1 because the base current is small.

The temperature compensation circuit 323 supplies the bias voltages Vb1 and Vb3, which vary in accordance with temperature characteristics of the Schottky barrier diode 327, to the base of the biasing transistor 322 and the anode of the Schottky barrier diode 327 through the node N1, respectively, on the basis of the battery voltage Vbat supplied from the battery voltage supply terminal 171.

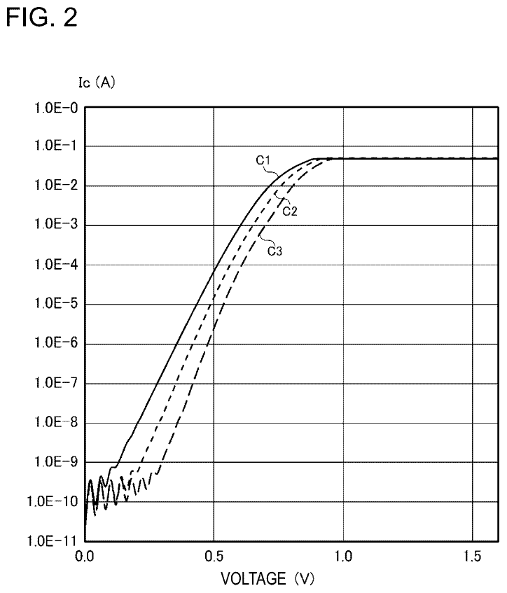

FIG. 2 is a graph illustrating an example of a change of V-I characteristics of the Schottky barrier diode 327 that depends on temperature. In FIG. 2, the horizontal axis represents a voltage between the anode and the cathode in units of “V”, and the vertical axis represents a forward current in units of “A” with a logarithmic axis.

As illustrated in FIG. 2, curves C1, C2, and C3 indicate the V-I characteristics of the Schottky barrier diode 327 at 85° C., 25° C., and −30° C., respectively. For example, the voltage between the anode and the cathode, when the forward current of 1 mA flows, decreases with a temperature rise.

That is, the threshold voltage Vths of the Schottky barrier diode 327 decreases with a temperature rise.

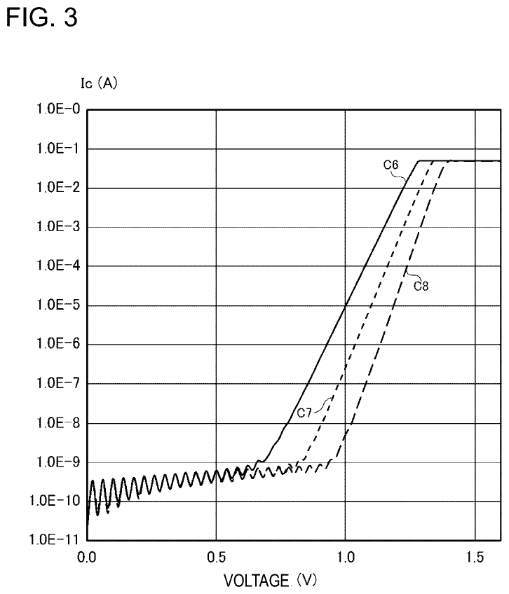

FIG. 3 is a graph illustrating an example of a change of V-I characteristics of an EB diode between an emitter and a base in a diode-coupled transistor that depends on temperature. FIG. 3 is viewed in the same way as FIG. 2.

As illustrated in FIG. 3, curves C6, C7, and C8 represent the V-I characteristics of the EB diode at 85° C., 25° C., and −30° C., respectively. When the curves C6, C7, and C8 and the curves C1, C2, and C3 illustrated in FIG. 2 are respectively compared, it is found that a threshold voltage of the EB diode is higher than the threshold voltage Vths of the Schottky barrier diode 327. That is, by using the Schottky barrier diode 327, the Schottky barrier diode 327 can be operated at the lower bias voltage Vb3.

As illustrated in FIG. 1, when the temperature of the Schottky barrier diode 327 falls, for example, the temperature compensation circuit 323 adjusts a voltage or a current to be outputted to the bias supply circuit 301 such that the bias voltages Vb1 and Vb3 increase. On the other hand, when the temperature of the Schottky barrier diode 327 rises, the temperature compensation circuit 323 adjusts a voltage or a current to be outputted to the bias supply circuit 301 such that the bias voltages Vb1 and Vb3 decrease.

The capacitor 326 has a first end coupled to the cathode of the Schottky barrier diode 327 and a second end coupled to the ground. The capacitor 326 is provided, for example, to stabilize a voltage of the cathode of the Schottky barrier diode 327.

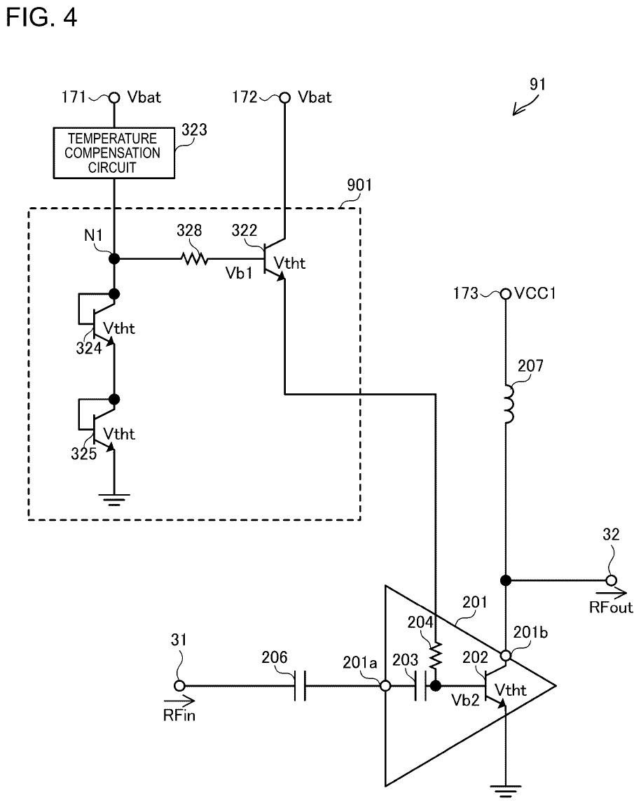

FIG. 4 is a circuit diagram of an RF amplification circuit 91 that is a first reference example of the RF amplification circuit 1. The RF amplification circuit 91 includes a bias supply circuit 901 instead of the bias supply circuit 301, as compared with the RF amplification circuit 1 illustrated in FIG. 1. The bias supply circuit 901 does not include the capacitor 326, the Schottky barrier diode 327, or the resistor 329, as compared with the bias supply circuit 301 illustrated in FIG. 1. That is, in the RF amplification circuit 91, a bias is supplied to the amplification transistor 202 only by the emitter follower circuit.

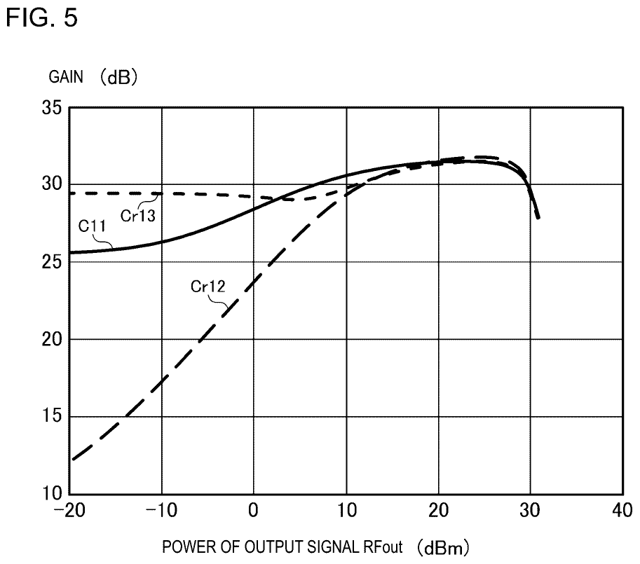

FIG. 5 is a graph illustrating an example of AM-AM characteristics. In FIG. 5, the horizontal axis represents power of the output signal RFout in units of “dBm”, and the vertical axis represents a gain in units of “dB”.

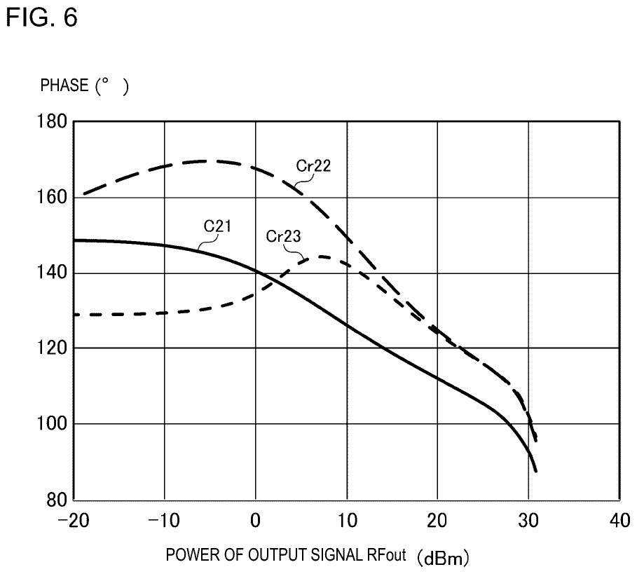

FIG. 6 is a graph illustrating an example of AM-PM characteristics. In FIG. 6, the horizontal axis represents power of the output signal RFout in units of “dBm”, and the vertical axis represents a phase in units of “°”

As illustrated in FIG. 5 and FIG. 6, curves C11 and C21 indicate the AM-AM characteristics and the AM-PM characteristics, respectively, when the battery voltage Vbat is low and the bias supply circuit 301 (see FIG. 1) supplies the bias voltage Vb2 to the base of the amplification transistor 202.

Curves Cr12 and Cr22 indicate the AM-AM characteristics and the AM-PM characteristics, respectively, when the battery voltage Vbat is low and the bias supply circuit 901 (see FIG. 4) supplies the bias voltage Vb2 to the base of the amplification transistor 202.

First, the improvement of the gain will be described. As illustrated in FIG. 5, when the battery voltage is lower than a battery voltage of a commonly used lithium-ion battery, the curve Cr12 indicates that the gain is small when the power of the output signal RFout is small, that is, when the power of the input signal RFin is small. In the case above, the DC collector current becomes substantially zero, and it is difficult to supply a bias to the amplification transistor 202 only by the emitter follower circuit.

The threshold voltage Vths of the Schottky barrier diode 327 is 0.6 V to 0.7 V, which is lower than the threshold voltage Vtht between the base and the emitter of the biasing transistor 322, that is, approximately 1.35 V. Thus, when the battery voltage Vbat is low, for example, such as approximately 2.7 V, the biasing transistor 322 does not operate, but the Schottky barrier diode 327 can be operated. As a result, a bias can be supplied to the amplification transistor 202.

Accordingly, the gain indicated by the curve C11, when the power of the output signal RFout is small, can be made larger than the gain indicated by the curve Cr12.

Further, since the biasing transistor 322 also operates when the power of the output signal RFout is large, the gain indicated by the curve C11, when the power of the output signal RFout is large, can be made substantially equal to the gain indicated by the curve Cr12.

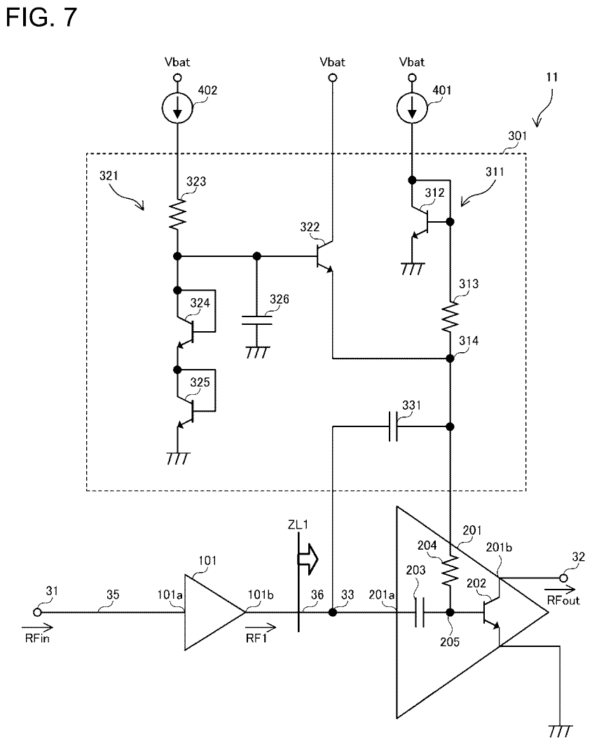

Next, the improvement of distortion characteristics will be described. FIG. 7 is a circuit diagram of an RF amplification circuit 11 described in Patent Document 2, which is a second reference example of the RF amplification circuit 1. As a method of improving the gain when the power of the output signal RFout is small, there is a method of supplying a bias to the amplification transistor 202 by a bias circuit 301 (hereinafter, may be referred to as a reference bias circuit) described in Patent Document 2.

As illustrated in FIG. 5 to FIG. 7, curves Cr13 and Cr23 indicate the AM-AM characteristics and the AM-PM characteristics, respectively, when the battery voltage Vbat is low and the reference bias circuit supplies a bias to the base of the amplification transistor 202.

The curve Cr13 has an inflection point at about 5 dBm and has a shape recessed in a direction in which the gain decreases (see FIG. 5). That is, the sign of the slope of the curve Cr13 changes with approximately 5 dBm as a boundary.

The curve Cr23 has an inflection point at approximately 8 dBm and has a shape rising in a direction in which the gain increases (see FIG. 6). That is, the sign of the slope of the curve Cr23 changes with approximately 8 dBm as a boundary.

When a curve has an inflection point, that is, the curve is not flat for the change of the power of the output signal RFout as in the curves Cr13 and Cr23, the distortion of the amplified signal outputted from the amplification transistor 202 increases.

In contrast, the curve C11 (see FIG. 5) monotonically increases in a range from −20 dBm to 20 dBm and has no inflection point. The curve C21 (see FIG. 6) monotonically decreases in the range from −20 dBm to 20 dBm and has no inflection point. This indicates that the distortion of the output signal RFout outputted from the amplification transistor 202 decreases in the RF amplification circuit 1.

Next, solution for bias shortage at a low temperature will be described. As described above, the temperature compensation circuit 323 increases the bias voltages Vb1 and Vb3 when the temperature of the Schottky barrier diode 327 falls, and decreases the bias voltages Vb1 and Vb3 when the temperature of the Schottky barrier diode 327 rises.

Thus, even when the temperature of the Schottky barrier diode 327 changes, it is possible to make an appropriate amount of forward current flow through the Schottky barrier diode 327. That is, when the battery voltage Vbat is low, and even when the biasing transistor 322 does not operate because the threshold voltage Vtht rises at a low temperature, the bias voltage Vb2 can be supplied to the base of the amplification transistor 202 by the Schottky barrier diode 327. Accordingly, even at a low temperature, the bias voltage Vb2 is appropriately supplied to the base of the amplification transistor 202, and thus it is possible to mitigate a decrease in gain due to bias shortage.

### Second Embodiment

A power amplification circuit according to a second embodiment will be described. In the second and subsequent embodiments, a description of matters in common with the first embodiment will be omitted, and only different points will be described. In particular, the same and/or similar effects of the same and/or similar configurations will not be described in each embodiment.

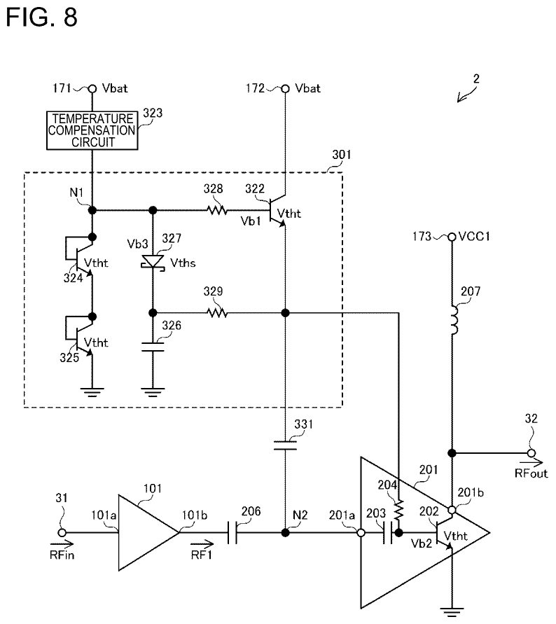

FIG. 8 is a circuit diagram of the RF amplification circuit 2. As illustrated in FIG. 8, the RF amplification circuit 2 according to the second embodiment is different from the RF amplification circuit 11 according to the first embodiment in that a capacitor 331 is provided which couples the emitter of the biasing transistor 322 and a node N2 between an amplifier 101 of an initial stage (driver stage) and the amplifier 201 of an output stage (power stage). The RF signal is picked up from the node N2 between the amplifier 101 and the amplifier 201 and added to the emitter of the biasing transistor 322.

The RF amplification circuit 2 further includes the amplifier 101 and the capacitor 331, as compared with the RF amplification circuit 1 illustrated in FIG. 1. The amplifiers 101 and 201 are amplifiers of the initial stage (driver stage) and the output stage (power stage), respectively. The amplifier 101 has the same and/or similar configuration as/to the amplifier 201.

An input terminal 101a of the amplifier 101 is coupled to the input terminal 31. An output terminal 101b of the amplifier 101 is coupled to the node N2 through the capacitor 206. The input terminal 201a of the amplifier 201 is coupled to the node N2.

The amplifier 101 amplifies an input signal RFin inputted from the input terminal 31 and outputs the amplified signal RF1 to the base of the amplification transistor 202.

The capacitor 331 has a first end coupled to the node N2 and a second end coupled to the emitter of the biasing transistor 322.

With the configuration above, the amplified signal RF1 added by the capacitor 331 can be supplied to the base of the amplification transistor 202. Because of that, the forward current in the Schottky barrier diode 327 can be reduced. As a result, the current supplied by the temperature compensation circuit 323 may be made small, and thus the circuit scale of the temperature compensation circuit 323 can be reduced.

In the RF amplification circuit 2, the configuration has been described in which the two-stage amplifier of the amplifier 101 and the amplification transistor 202 is provided, but the configuration is not limited thereto. The RF amplification circuit 2 may have a configuration in which the amplifier 101 is not provided. That is, even in a case of a single-stage amplification circuit, by providing the capacitor 331 between the input terminal 201a of the amplification transistor 202 and the emitter of the biasing transistor 322, the input signal RFin added by the capacitor 331 can be supplied to the base of the amplification transistor 202.

In the RF amplification circuits 1 and 2, the configuration has been described in which the Schottky barrier diode 327 is provided, but the configuration is not limited thereto. Instead of the Schottky barrier diode 327, another type of diode having a threshold voltage lower than a threshold voltage of an EB diode or a BC diode may be provided.

In the RF amplification circuits 1 and 2, the configuration has been described in which the transistors such as the amplification transistor 202 and the biasing transistor 322 are made of a compound semiconductor containing gallium arsenide as a main component, but the configuration is not limited thereto.

Exemplary embodiments of the present disclosure have been described above. In the RF amplification circuits 1 and 2, the amplification transistor 202 includes the base to which the input signal RFin is supplied and the collector from which the amplified input signal RFin is outputted. The amplification transistor 202 is made of a compound semiconductor. The biasing transistor 322 has the base to which the bias voltage Vb1 is supplied, and the emitter electrically coupled to the base of the amplification transistor 202 and to supply the bias voltage Vb2 to the base of the amplification transistor 202. The biasing transistor 322 is made of the compound semiconductor. The Schottky barrier diode 327 has the anode electrically coupled to the base of the biasing transistor 322 and the cathode electrically coupled to the emitter of the biasing transistor 322.

In a case of the compound semiconductor, a threshold voltage of a transistor may become high. Thus, when a low battery voltage Vbat is supplied to the RF amplification circuit and the power of the input signal RFin is low, no bias voltage Vb1, with a level at which the biasing transistor 322 can operate, may be supplied to the base of the biasing transistor 322. In contrast, the above configuration allows the Schottky barrier diode 327 to operate, and thus the bias voltage Vb2 may be supplied to the base of the amplification transistor 202 by the forward current flowing through the Schottky barrier diode 327. Accordingly, it is possible to provide an RF amplification circuit including a transistor made of a compound semiconductor, which can increase a gain when the power of an input signal is low at a low voltage. When the power of an input signal RFin is large, the biasing transistor 322 can be operated, and thus the bias voltage Vb2 can be sufficiently supplied to the base of the amplification transistor 202 by the biasing transistor 322. Thus, the forward current in the Schottky barrier diode 327 can be reduced, and therefore the circuit scale of the temperature compensation circuit 323 that supplies the bias voltages Vb1 and Vb3 can be reduced.

In the RF amplification circuits 1 and 2, the compound semiconductor is a semiconductor containing gallium arsenide as a main component.

With the configuration above, the threshold voltage Vtht of each of the amplification transistor 202 and the biasing transistor 322 increases to approximately 1.35 V, but the battery voltage Vbat that exceeds twice the voltage of 1.35 V is optional, and the battery voltage Vbat may be lowered to a level at which the Schottky barrier diode 327 operates. That is, the battery voltage Vbat may effectively be lowered.

In the RF amplification circuits 1 and 2, the amplification transistor 202 has the base to which the input signal RFin is supplied and the collector from which the amplified input signal RFin is outputted. The biasing transistor 322 has the base to which the Vb1 is supplied, and the emitter electrically coupled to the base of the amplification transistor 202 and to supply the bias voltage Vb2 to the base of the amplification transistor 202. The Schottky barrier diode 327 has the anode electrically coupled to the base of the biasing transistor 322 and the cathode electrically coupled to the emitter of the biasing transistor 322. The threshold voltage of the Schottky barrier diode 327 is lower than the threshold voltage Vtht of the biasing transistor 322.

When the low battery voltage Vbat is supplied to the RF amplification circuit and the power of the input signal RFin is low, no bias voltage Vb1, with a level at which the biasing transistor 322 can operate, may be supplied to the base of the biasing transistor 322. In contrast, as described above, the configuration in which the threshold voltage of the Schottky barrier diode 327 is lower than the threshold voltage Vtht of the biasing transistor 322 allows the Schottky barrier diode 327 to operate even with the bias voltage Vb1 at which the biasing transistor 322 does not operate. Thus, the bias voltage Vb2 can be supplied to the base of the amplification transistor 202 by the forward current flowing through the Schottky barrier diode 327. Accordingly, it is possible to provide an RF amplification circuit including a transistor made of a compound semiconductor, which can increase a gain when the power of an input signal is low at a low voltage. When the power of an input signal RFin is large, the biasing transistor 322 can be operated, and thus the bias voltage Vb2 can be sufficiently supplied to the base of the amplification transistor 202 by the biasing transistor 322. Thus, the forward current in the Schottky barrier diode 327 can be reduced, and therefore the circuit scale of the temperature compensation circuit 323 that supplies the bias voltages Vb1 and Vb3 can be reduced.

In the RF amplification circuits 1 and 2, the threshold voltage of the Schottky barrier diode 327 is lower than the threshold voltage Vtht of the biasing transistor 322.

As described above, the configuration in which the threshold voltage of the Schottky barrier diode 327 is lower than the threshold voltage Vtht of the biasing transistor 322 allows the Schottky barrier diode 327 to operate even with the bias voltage Vb1 at which the biasing transistor 322 does not operate. Thus, the bias voltage Vb2 can be supplied to the base of the amplification transistor 202 by the forward current flowing through the Schottky barrier diode 327.

In the RF amplification circuits 1 and 2, the temperature compensation circuit 323 supplies the bias voltage Vb1 that varies in accordance with the temperature characteristics of the Schottky barrier diode 327 to the base of the biasing transistor 322.

With the configuration above, even when the temperature of the Schottky barrier diode 327 changes and the threshold voltage of the Schottky barrier diode 327 changes, the Schottky barrier diode 327 can appropriately be operated with the bias voltage Vb1 supplied by the temperature compensation circuit 323. Thus, the bias voltage Vb2 may appropriately be supplied to the base of the amplification transistor 202 regardless of the temperature of the Schottky barrier diode 327.

In the RF amplification circuits 1 and 2, the collector of the biasing transistor 322 is supplied with the battery voltage Vbat. The emitter of the biasing transistor 322 is electrically coupled to the base of the amplification transistor 202 through the resistor 204. When the battery voltage Vbat is low, the biasing transistor 322 does not operate and the Schottky barrier diode 327 operates.

With the configuration above, when the battery voltage Vbat is low, the bias voltage Vb2 can be supplied to the base of the amplification transistor 202 by the forward current flowing through the Schottky barrier diode 327.

In the RF amplification circuit 2, the capacitor 331 has the first end electrically coupled to the base of the amplification transistor 202 and the second end electrically coupled to the emitter of the biasing transistor 322.

With the configuration above, part of the amplified signal RF1 can be supplied to the emitter of the biasing transistor 322 through the capacitor 331, and thus phases of the bias voltage Vb2 and a current supplied to the base of the amplification transistor 202 can be matched. This makes it possible to suppress a change in an output phase of the output signal RFout for the power of the output signal RFout. That is, suitable AM/PM characteristics can be achieved. Accordingly, it is possible to provide an RF amplification circuit that suppresses the fluctuation of the output phase of the output signal RFout regardless of the power of the output signal RFout.

In the RF amplification circuit 2, the amplifier 101 amplifies the input signal Rfin inputted thereto and outputs the amplified signal to the base of the amplification transistor 202.

With the configuration above, the amplified input signal RFin detected by the capacitor 331 may be supplied to the base of the amplification transistor 202, and thus the forward current in the Schottky barrier diode 327 can be reduced. Thus, the circuit scale of the temperature compensation circuit 323 that supplies the bias voltages Vb1 and Vb3 can further be reduced.

The embodiments described above are intended to facilitate understanding of the present disclosure and are not intended to limit and interpret the present disclosure. The present disclosure can be modified or improved without necessarily departing from the gist thereof, and the present disclosure includes equivalents thereof. That is, those skilled in the art may appropriately modify the design of each embodiment, and such modifications are also encompassed within the scope of the present disclosure as long as they have the features of the present disclosure. For example, the elements included in the embodiments and the arrangement, materials, conditions, shapes, sizes, and the like thereof are not limited to those exemplified and may appropriately be changed. Further, the embodiments are merely illustrative, and it is needless to say that partial replacement or combination of configurations illustrated in different embodiments is possible, and these are also included in the scope of the present disclosure as long as they include the features of the present disclosure.

<1>

A radio frequency amplification circuit, comprising:
an amplification transistor having a base to which a radio frequency signal is supplied and a collector from which the radio frequency signal amplified is outputted, the amplification transistor made of a compound semiconductor;
a first transistor having a base to which a first bias is supplied and an emitter electrically coupled to the base of the amplification transistor and configured to supply a second bias to the base of the amplification transistor, the first transistor made of the compound semiconductor; and
a Schottky barrier diode having an anode electrically coupled to the base of the first transistor and a cathode electrically coupled to the emitter of the first transistor.
   <2>

The radio frequency amplification circuit according to <1>,
wherein the compound semiconductor is a semiconductor containing gallium arsenide as a main component.
   <3>

A radio frequency amplification circuit, comprising: an amplification transistor having a base to which a radio frequency signal is supplied and a collector from which the radio frequency signal amplified is outputted;
a first transistor having a base to which a first bias is supplied and an emitter electrically coupled to the base of the amplification transistor and configured to supply a second bias to the base of the amplification transistor; and
a Schottky barrier diode having an anode electrically coupled to the base of the first transistor and a cathode electrically coupled to the emitter of the first transistor,
wherein a threshold voltage of the Schottky barrier diode is lower than a threshold voltage of the first transistor.
   <4>

The radio frequency amplification circuit according to <1>or <2>,
wherein a threshold voltage of the Schottky barrier diode is lower than a threshold voltage of the first transistor.
   <5>

The radio frequency amplification circuit according to any one of <1>to <4>, further comprising
a temperature compensation circuit configured to supply the first bias to the base of the first transistor, the first bias varying in accordance with temperature characteristics of the Schottky barrier diode.
   <6>

The radio frequency amplification circuit according to any one of <1>to <5>,
wherein a collector of the first transistor is supplied with a battery voltage,
the emitter of the first transistor is electrically coupled to the base of the amplification transistor through a resistor, and
when the battery voltage is low, the first transistor does not operate and the Schottky barrier diode operates.
   <7>

The radio frequency amplification circuit according to any one of <1>to <6>, further comprising
a capacitor having a first end electrically coupled to the base of the amplification transistor and a second end electrically coupled to the emitter of the first transistor. <8>

The radio frequency amplification circuit according to <7>, further comprising
an amplifier configured to amplify a radio frequency signal inputted and to output the radio frequency signal amplified to the base of the amplification transistor.

### REFERENCE SIGNS LIST

1, 2 RF AMPLIFICATION CIRCUIT
31 INPUT TERMINAL
32 OUTPUT TERMINAL
91 RF AMPLIFICATION CIRCUIT
101 AMPLIFIER
171, 172 BATTERY VOLTAGE SUPPLY TERMINAL
173 POWER VOLTAGE SUPPLY TERMINAL
201 AMPLIFIER
202 AMPLIFICATION TRANSISTOR
203 CAPACITOR
204 RESISTOR
206 CAPACITOR
207 INDUCTOR
301 BIAS SUPPLY CIRCUIT
322 BIASING TRANSISTOR
323 TEMPERATURE COMPENSATION CIRCUIT
324, 325 TRANSISTOR
326 CAPACITOR
327 SCHOTTKY BARRIER DIODE
328, 329 RESISTOR
331 CAPACITOR
901 BIAS SUPPLY CIRCUIT

1. A radio frequency amplification circuit, comprising:
an amplification transistor made of a compound semiconductor, having a base supplied with a radio frequency signal and a collector configured to output an amplified radio frequency signal;
a first transistor made of the compound semiconductor and having a base supplied with a first bias, and an emitter electrically coupled to the base of the amplification transistor, the first transistor being configured to supply a second bias to the base of the amplification transistor; and
a Schottky barrier diode having an anode electrically coupled to the base of the first transistor and a cathode electrically coupled to the emitter of the first transistor.

2. The radio frequency amplification circuit according to claim 1, wherein the compound semiconductor is a semiconductor containing gallium arsenide as a main component.

3. A radio frequency amplification circuit, comprising:
an amplification transistor having a base supplied with a radio frequency signal and a collector configured to output an amplified radio frequency signal;
a first transistor having a base supplied with a first bias and an emitter electrically coupled to the base of the amplification transistor, the first transistor being configured to supply a second bias to the base of the amplification transistor; and
a Schottky barrier diode having an anode electrically coupled to the base of the first transistor and a cathode electrically coupled to the emitter of the first transistor,
wherein a threshold voltage of the Schottky barrier diode is lower than a threshold voltage of the first transistor.

4. The radio frequency amplification circuit according to claim 1, wherein a threshold voltage of the Schottky barrier diode is lower than a threshold voltage of the first transistor.

5. The radio frequency amplification circuit according to claim 1, further comprising:
a temperature compensation circuit configured to supply the first bias to the base of the first transistor, such that the first bias varies in accordance with temperature characteristics of the Schottky barrier diode.

6. The radio frequency amplification circuit according to

1.,
wherein a battery voltage is supplied to a collector of the first transistor,
wherein the emitter of the first transistor is electrically coupled to the base of the amplification transistor through a resistor, and
wherein when the battery voltage is low, the first transistor is configured to not operate and the Schottky barrier diode is configured to operate.

7. The radio frequency amplification circuit according to claim 1, further comprising:
a capacitor having a first end electrically coupled to the base of the amplification transistor and a second end electrically coupled to the emitter of the first transistor.

8. The radio frequency amplification circuit according to claim 7, further comprising:
an amplifier configured to amplify an inputted radio frequency signal and to output the radio frequency signal to the base of the amplification transistor.

9. The radio frequency amplification circuit according to claim 3, further comprising:
a temperature compensation circuit configured to supply the first bias to the base of the first transistor, such that the first bias varies in accordance with temperature characteristics of the Schottky barrier diode.

10. The radio frequency amplification circuit according to claim 3,
wherein a battery voltage is supplied to a collector of the first transistor,
wherein the emitter of the first transistor is electrically coupled to the base of the amplification transistor through a resistor, and
wherein when the battery voltage is low, the first transistor is configured to not operate and the Schottky barrier diode is configured to operate.

11. The radio frequency amplification circuit according to claim 3, further comprising:
a capacitor having a first end electrically coupled to the base of the amplification transistor and a second end electrically coupled to the emitter of the first transistor.

12. The radio frequency amplification circuit according to claim 11, further comprising:
an amplifier configured to amplify an inputted radio frequency signal and to output the radio frequency signal to the base of the amplification.
